(19) United States
(12) Patent Application Publication
(10) Pub. No.: US 2007/0080426 A1
(43) Pub. Date: Apr. 12, 2007

(54) Single lithography-step planar metal-insulator-metal capacitor and resistor

(75) Inventors: Phillip D. Matz, McKinney, TX (US); Sameer Ajmera, Richardson, TX (US); Darius Crenshaw, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/246,249

(22) Filed: Oct. 11, 2005

(51) Int. Cl. H01L 29/00

(52) U.S. Cl. 257/516

(57) ABSTRACT

MIMCAP semiconductor devices and methods for fabrication MIMCAP semiconductor devices that include a grown capacitor dielectric are provided. Exemplary MIMCAP semiconductor devices can include a bottom electrode, a grown capacitor dielectric on the bottom electrode, and a top electrode on the capacitor dielectric. The grown layer can have a k-value greater than 1 and can be formed of, for example, an oxide or nitride that is chemically or thermally grown from the bottom electrode.

### DESCRIPTION OF THE INVENTION

1. Field of the Invention

The present invention relates to semiconductor devices and methods for making semiconductor devices. More particularly, the present invention relates to metal-insulator-metal capacitors and methods for making metal-insulator-metal capacitors that include a grown capacitor dielectric layer.

2. Background of the Invention

A metal-insulator-metal capacitor (MIMCAP) is a semiconductor device often used in, for example, mixed signal devices and logic devices. A conventional MIMCAP includes a bottom electrode and a top electrode separated by a capacitor dielectric layer. The capacitor dielectric layer is often deposited by plasma enhanced chemical vapor deposition, sputtering, or evaporation.

Fabrication of conventional MIMCAPs consists of providing a substrate and depositing a first conductive layer over the substrate. A capacitor dielectric layer is then deposited over the first conductive layer. A second conductive layer is deposited over the capacitor dielectric layer. In the case of MIMCAP structures, the conductive layers are composed of metals or metal containing alloys. Depending on the thickness of the second conductive layer, an etch stop layer can be deposited over the second conductive layer to serve as an etch stop when vias or other electrical connections are formed to make electrical contact to the second conductive layer.

A top electrode is formed from the second conductive layer and a bottom electrode is formed from the first conductive layer. To form the top electrode, a photoresist is deposited over the etch stop layer and the second conductive layer, and patterned. Using the photoresist as a mask, the etch stop layer and the second conductive layer are patterned, using etching, to form the top electrode. In some integration schemes, it may be desirable to pattern or etch the bottom electrode before or after the deposition of any subsequent layers.

Problems arise, however, as the demand and cost for MIMCAPs, for example, embedded in back-end-of-line (BEOL) integrated circuits increases. To achieve higher capacitance, either thinner dielectric layers or dielectric layers possessing higher dielectric constants (also called k-value) are required as capacitance scales inversely with capacitor dielectric thickness. However, as the capacitor dielectric becomes thinner, reliability (device lifetime), dielectric breakdown strength, and TDDB (time-dependent dielectric breakdown) decrease. Further, state-of-the-art BEOL integration has moved to copper metallization for metal interconnect structures. Copper, though excellent for reducing resistivity in interconnects, is difficult to integrate with MIMCAP structures because it diffuses readily through many common dielectrics, thereby shorting the capacitor or at the very least exacerbating the reduction in device lifetime.

Conventional solutions exist to resolve some of the above issues, but those solutions require additional photolithography steps. Because the cost of an additional photolithographic pattern step will typically represent a significant fraction of the overall expected return-on-investment for manufacturing the semiconductor device, conventional solutions add undesirable complexity and cost to the fabrication process.

Thus, there is a need to overcome these and other problems of the prior art and to provide MIMCAPs and methods for fabrication of MIMCAPs with lower fabrication costs and higher performance.

### SUMMARY OF THE INVENTION

According to various embodiments, the present teachings include a metal-insulator-metal capacitor (MIMCAP). The MIMCAP can include a bottom electrode and a grown layer disposed on a surface of the bottom electrode. The grown layer can have a k-value greater than 1. The MIMCAP can further include a top electrode disposed on the grown layer.

According to various other embodiments, the present teachings include a method of making a metal-insulator-metal capacitor (MIMCAP). The method can include depositing a first conductive layer on a substrate. A capacitor dielectric layer can then be grown from the first conductive layer, where the capacitor dielectric layer has a k-value greater than 1. A second conductive layer can be deposited on the capacitor dielectric layer.

According to other embodiments, the present teachings include another method of making a metal-insulator-metal capacitor (MIMCAP). The method can include patterning a mask layer to expose a portion of a first conductive layer. A capacitor dielectric layer can be grown from the first conductive layer, where the grown capacitor dielectric layer has a k-value greater than 1. An etch stop layer can be deposited on the grown capacitor dielectric layer and an insulating layer and resist layer can be deposited on the etch stop layer. A via structure can be formed in the insulating layer after the resist layer is patterned and a second conductive layer can be deposited in the via structure. The second conductive layer can make electrical contact with the grown capacitor dielectric layer.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 depicts a MIMCAP structure according to various erribodiments of the present teachings.

FIG. 2A depicts a step of depositing a dielectric etch stop layer over a conductive layer during fabrication of a MIMCAP according to various embodiments of the present teachings.

FIG. 2B depicts a step of exposing a bottom electrode during fabrication of a MIMCAP according to various embodiments of the present teachings.

FIG. 2C depicts a step of thermally growing a layer during fabrication of a MIMCAP according to various embodiments of the present teachings.

FIG. 2D depicts a step of forming an insulating layer on a thermally grown layer.

FIG. 2E.depicts a step of forming a top electrode during fabrication of a MIMCAP according to various embodiments of the present teachings.

FIG. 2F depicts a MIMCAP structure formed according to various embodiments of the present teachings.

FIG. 3A depicts a step of forming a bottom electrode during fabrication of a MIMCAP according to various embodiments of the present teachings.

FIG. 3B depicts a step of growing a thermally grown layer during fabrication of a MIMCAP according to various embodiments of the present teachings.

FIG. 3C depicts a step of forming a etch stop layer and an insulating layer during fabrication of a MIMCAP according to various embodiments of the present teachings.

FIG. 3D depicts a step of forming a top electrode during fabrication of a MIMCAP according to various embodiments of the present teachings.

### DESCRIPTION OF THE EMBODIMENTS

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

As used herein and unless otherwise specified, the term “growing a layer” and “grown layer” refer to a layer that includes atoms or molecules from an underlying layer, such as, for example, the grown layer can be an oxide formed by oxidation of the underlying layer or a nitride formed by nitridation of the underlying layer. Other materials, however, can also be used.

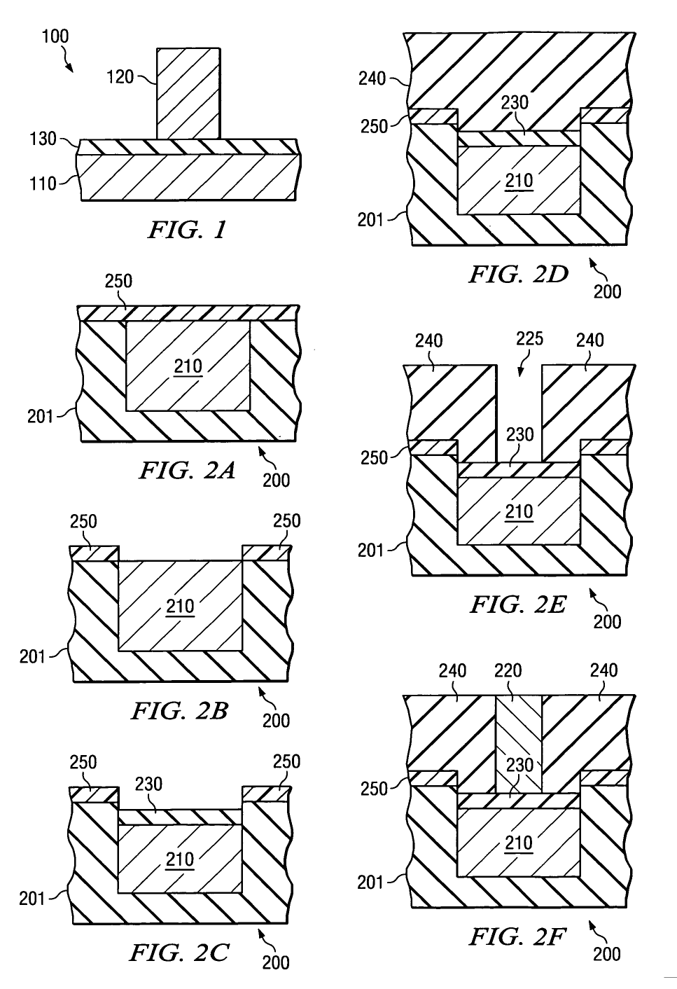

FIGS. 1 through 3D depict exemplary MIMCAP semiconductor devices and methods for fabrication of exemplary MIMCAP semiconductor devices that include a grown layer disposed on a bottom electrode. The grown layer can be, for example, a layer grown by oxidizing or nitriding the bottom electrode and having a k-value greater than 1.

According to various embodiments and as shown in FIG. 1, a MIMCAP 100 can include a bottom electrode 110 and a top electrode 120. MIMCAP 100 can further include a grown layer 130. Bottom electrode 110 can be a conductive layer, such as, for example, a copper layer, a tantalum layer, a titanium layer, an aluminum layer, a COWP deposited capping layer or combinations thereof. In some embodiments, bottom electrode 110 can be polysilicon or silicide. Top electrode 120 can be a conductive layer formed of a material including, but not limited to copper, tantalum, titanium, aluminum, or CoWP deposited capping layer or combinations thereof.

According to various embodiments, grown layer 130 can be a capacitor dielectric layer having a k-value greater than 1. Grown layer can be formed of, for example, an oxide or a nitride that is thermally or chemically grown from bottom electrode 110. Thus, some exemplary bottom electrode/capacitor dielectric layer combinations for MIMCAP 100 include copper/copper oxide, tantalum/tantalum oxide, titanium/titanium oxide, and aluminum/aluminum oxide. Grown layer 130 can have a thickness of, for example, 1500 Åor less. Moreover, in various embodiments, grown layer 130 can have a capacitance density of at least about 1.5 fF/μm². In various other embodiments, grown layer 130 can have a capacitance density of at least about 3 fF/μm².

According to various embodiments, grown layer 130 can have a k-value of greater than about 3.0. According to other embodiments, grown layer 130 can have a k-value of greater than about 6.8.

In one exemplary embodiment, MIMCAP 100 can be formed using copper metal technology employed in CMOS BEOL fabrication. For example, bottom electrode 110 can be formed of copper, grown layer 130 can be formed of copper oxide, and top electrode 120 can be formed of copper. Copper oxide can have a dielectric constant of approximately 18, so grown layer 130 can have a thickness of about 50 nm to provide a capacitance of about 3 fF/μm².

Referring to FIGS. 2A-2F, an exemplary method for fabrication of exemplary MIMCAPs according to various embodiments is disclosed. FIG. 2A depicts a substrate 201 and a bottom electrode 210. Substrate 201 can be formed of, for example, single-crystal silicon, silicon-on-insulator (SOI) or compound semiconductors such as, for example, GaAs, InP, Si/Ge, and SiC. Substrate 201 can further include semiconductor elements such as transistors, diodes, field oxides, active component regions, shallow trench isolation or deep trench isolation regions, and/or other related or unrelated semiconductor devices, circuitry, components, or interconnect layers, all of which are not shown. FIG. 2A shows a point in the fabrication process after a first conductive layer has been formed in substrate 201 to form bottom electrode 210, and a dielectric etch stop layer 250 has been deposited on a top surface of bottom electrode 210 and substrate 201. Bottom electrode 210 can be formed by, for example, ECD (electro-chemical deposition) coupled with CMP (chemical-mechanical polish) as is done in a standard damascene fabrication methodology and would be familiar to one of ordinary skill in the art.

Referring to FIG. 2B, dielectric etch stop layer 250 can be patterned and etched to expose a top surface of bottom electrode 210. Standard photolithography techniques employing photo-sensitive resists and lithography masks (not shown) can be used to define and expose bottom electrode 210 and would be familiar to one of ordinary skill in the art. Patterned and etched layer 250 can expose a desired region of bottom electrode 210 to a subsequent oxidation process, protecting any other region from undesired oxidation.

As shown in FIG. 2C, a grown layer 230 can be formed on the top surface of bottom electrode 210. Grown layer 230, having a k-value greater than 1, can be formed on the top surface of bottom electrode 210 by, for example, thermally oxidizing to form an oxide layer or thermally nitriding to form a nitride layer. For example, a typical nitridization processes can occur with the assistance of plasma enhanced environments employing either nitrogen or ammonia as precursors in the plasma to affect elevated nitridation reaction rates at the exposed surface of conductive bottom electrode 210. In various embodiments, grown layer 230 can be a capacitor dielectric layer having a thickness of 1500 Åor less. In various embodiments, grown layer 230 can be a capacitor dielectric layer having a capacitance of at least about 1.5 fF/μm². In various other embodiments, grown layer 230 can be a capacitor dielectric layer having a capacitance of at least about 3 fF/μm².

In an exemplary embodiment, grown layer 230 can be formed by thermal oxidation of a copper bottom electrode 210 to form a copper oxide as follows:
Cu(solid)+O₂(gas)+Heat→X CuO(solid)+(1−X) Cu₂O(solid), where X varies from 0 to 1.

In another exemplary embodiment, grown layer 230 can be formed by chemical oxidation of copper bottom electrode 210 to form a copper oxide as follows:
Cu(solid)+H₂O₂(liquid)+H₂O(liquid)→X CuO(solid)+(1−X) Cu₂O(solid), where X varies from 0 to 1.

In another exemplary embodiment, grown layer 230 can be formed by oxidation of copper bottom electrode 210 to form a copper oxide using a plasma as follows
Cu(solid)+O₂(gas)+plasma→X CuO(solid)+(1−X) Cu₂O(solid), where X varies from 0 to 1.

As shown in FIG. 2D, an insulating layer 240 can be formed on grown layer 230, dielectric etch stop layer 250, and a portion of substrate 201. Insulating layer 240 can be, for example, any of a variety of dielectrics used in BEOL integration including, but not limited to, oxides, carbon doped oxides, carbides, nitrides, oxy-carbides, oxy-nitrides, low dielectric constant, mesoporous, and microporous low dielectric constant dielectrics, fluoro-silicate glasses (FSG), or organic based low-k materials. Referring to FIG. 2E, a via 225 can then be formed in insulating layer 240. A conductive material can be deposited in via 225 to form a top electrode 220, as shown in FIG. 2F. This process, in certain embodiments, can be integrated into standard single or dual damascene methodology that would be familiar to one of ordinary skill in the art. One of ordinary skill in the art will also recognize that this process can include formation of additional structures, such as, for example, a trench structure using trench-first-via-last or via-first-trench-last methodology. Further, in certain embodiments, the formation of via structure 230 can be done in parallel to the formation of other unrelated via structures that would be part of the interconnect of the semiconductor device as a whole. When via structure 230 is formed along with other desired vias for other interconnect structures, no additional photolithographic patterning step is necessary as both MIMCAP and non-MIMCAP vias can be patterned and etched together, providing substantial cost savings. MIMCAP 200 includes a top electrode 220, grown capacitor dielectric 230, and bottom electrode 210. Grown capacitor dielectric 230 can have a thickness of, for example, 1500 Åor less.

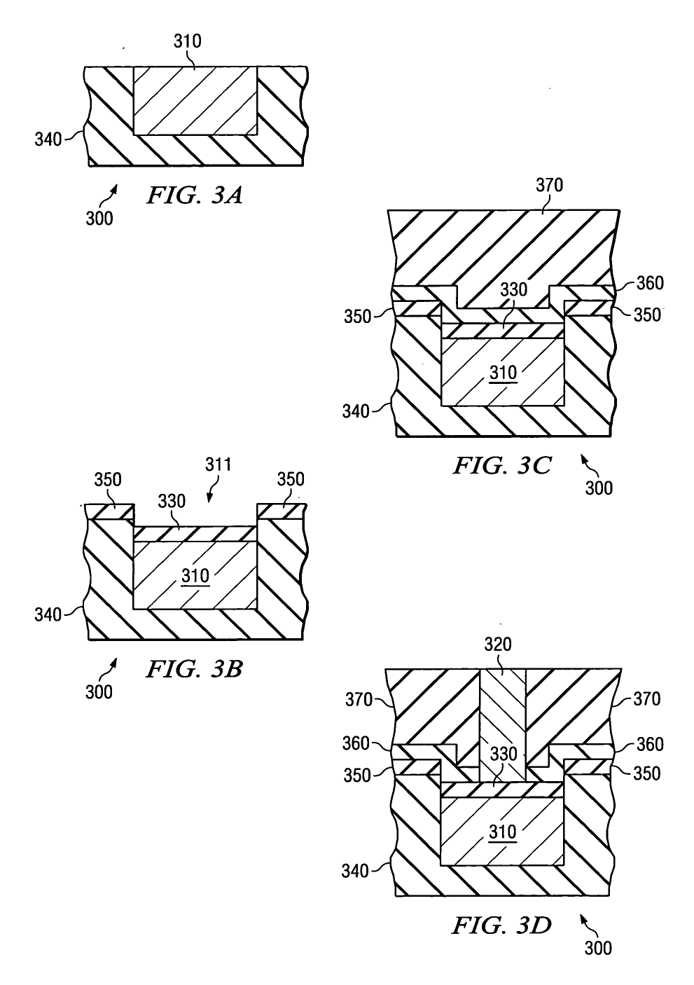

Referring to FIGS. 3A-3D, an exemplary method for fabrication of a MIMCAP that includes a single lithographic step according to various embodiments is disclosed. FIG. 3A depicts a substrate 340 and a bottom electrode 310. Substrate 340 can be formed of, for example, single-crystal silicon, silicon-on-insulator (SOI) or compound semiconductors such as, for example, GaAs, InP, SVGe, and SiC. Substrate 340 can further include semiconductor elements such as transistors, diodes, field oxides, active component regions, shallow trench isolation or deep trench isolation regions, and/or other related or unrelated semiconductor devices, circuitry, components, or interconnect layers, all of which are not shown. FIG. 3A shows a point in the fabrication process after a first conductive layer has been formed in substrate 340 to form bottom electrode 310. Bottom electrode 310 can be formed by, for example, ECD (electro-chemical deposition) coupled with CMP (chemical-mechanical polish) as is done in a standard damascene fabrication methodology and would be familiar to one of ordinary skill in the art.

Referring to FIG. 3B, dielectric layer 350 can be a hard mask formed of, for example, silicon nitride, silicon carbide, silicon-carbonitride, or silicon-oxynitride. Dielectric layer 350 can be patterned and etched to expose a top surface of first conductive layer 310. A grown capacitor dielectric layer 330 can then be formed on the top surface of first conducting layer 310. Grown capacitor dielectric layer 330, having a k-value greater than 1, can be formed on the top surface of first conducting layer 310 by, for example, thermally oxidizing to form an oxide layer or thermally nitriding to form a nitride layer. In various embodiments, grown capacitor dielectric layer 330 can have a thickness of 1500 Åor less. In various embodiments, grown capacitor dielectric layer 330 can have a capacitance of at least about 1.5 fF/μm². In various other embodiments, grown capacitor dielectric layer 330 can be a capacitor dielectric layer having a capacitance of at least about 3 fF μm².

In an exemplary embodiment, grown layer 330 can be a copper oxide formed by thermal oxidation, chemical oxidation, or plasma oxidation of a copper first conductive layer 310. Grown capacitor dielectric 330 can have a thickness of, for example, 1500 Åor less. Moreover, in various embodiments, grown capacitor dielectric 330 can have a capacitance density of at least about 1.5 fF/μm². In various other embodiments, grown capacitor dielectric 330 can have a capacitance density of at least about 3 fF/μm².

As shown in FIG. 3C, and an etch stop layer 360 can be formed on hardmask layer 350. In various embodiments, etch stop layer 360 can be conformal as depicted in FIG. 3C. A second insulating layer 370 can then be formed on etch stop layer 360. In various embodiments, etch stop layer 360 can be formed of SiCN. Second insulating layer 370 can be formed of, for example, any inter-level dielectric layer. Second insulating layer 370 can be formed of, for example, silicon dioxide or fluorinated silica glass.

Referring to FIG, 3D, a via can be formed to expose the top surface of grown capacitor dielectric layer 330. A second conducting layer 320 can then be deposited in the via to function as a top electrode. Second conducting layer 320 can be formed of, for example, copper. Thus, MIMCAP 300 can include top electrode/via 320, grown capacitor dielectric 330, and bottom electrode 310.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A metal-insulator-metal capacitor (MIMCAP) comprising:
a bottom electrode;
a grown layer disposed on a surface of the bottom electrode, wherein the grown layer has a k-value greater than 1; and
a top electrode disposed on the grown layer.

2. The MIMCAP of claim 1, wherein the bottom electrode comprises one of a copper layer, a tantalum layer, a titanium layer, an aluminum layer, a COWP deposited capping layer, a polysilicon layer, and a silicided layer.

3. The MIMCAP of claim 1, wherein the grown layer comprises at least one of an oxide and a nitride.

4. The MIMCAP of claim 1, wherein the grown layer has a thickness of less than 1500 Å.

5. The MIMCAP of claim 1, wherein the grown layer has a capacitance density of at least about 1.5 fF/μm².

6. The MIMCAP of claim 1, wherein the grown layer has a capacitance density of at least about 3 fF/μm².

7. A method of making a metal-insulator-metal capacitor (MIMCAP) comprising:
depositing a first conductive layer on a substrate;
growing a capacitor dielectric layer from the first conductive layer, wherein the capacitor dielectric layer has a k-value greater than 1;
depositing a second conductive layer on the capacitor dielectric layer.

8. The method of 7, wherein the step of growing a capacitor dielectric layer from the first conductive layer comprises chemically growing an oxide on the surface of the first conductive layer using one of an O₂ plasma, an O₂ anneal, and a wet-acid growth.

9. The method of 7, wherein the step of growing a capacitor dielectric layer on the first conductive layer comprises chemically growing a nitride on the surface of the first conducting layer.

10. The method of 7, wherein the step of growing a capacitor dielectric layer on the first conductive layer comprises growing the capacitor dielectric layer to a thickness of about 1500 Åor less.

11. The method of 7, wherein the step of growing a capacitor dielectric layer on the first conductive layer comprises growing a copper oxide layer.

12. The method of 7, wherein the step of growing a capacitor dielectric layer comprises growing a tantalum oxide layer.

13. A method of making a metal-insulator-metal capacitor (MIMCAP) comprising:
patterning a mask layer to expose a portion of a first conductive layer;
growing a capacitor dielectric layer from the first conductive layer, wherein the grown capacitor dielectric layer has a k-value greater than 1;
depositing an etch stop layer on the grown capacitor dielectric layer and the resist layer;
depositing a insulating layer on the etch stop layer;
forming a via structure in the insulating layer; and
depositing a second conductive layer in the via structure, wherein the second conductive layer makes electrical contact with the grown capacitor dielectric layer.

14. The method of claim 13, further comprising forming a trench structure.

15. The method of claim 13, wherein the step of patterning the mask layer to expose a portion of a first conductive layer comprises patterning one of a silicon nitride, a silicon carbide, silicon carbonitride, silicon oxynitride and a oxy-carbide layer.

16. The method of claim 13, wherein the step of forming a via structure in the insulating layer comprises etching through the insulating layer, the etch stop layer and the mask layer to expose a portion of the grown capacitor dielectric layer.

17. The method of claim 13, wherein the step of growing a capacitor dielectric layer on the first conductive layer comprises thermally growing an oxide layer.

18. The method of claim 13, wherein the step of growing a capacitor dielectric layer on the first conductive layer comprises growing a nitride layer.

19. The method of claim 13, wherein the step of growing a capacitor dielectric layer on the first conductive layer comprises growing an oxide layer using one of an O₂ plasma, an O₂ anneal, and a wet-acid growth.

20. The method of claim 13, wherein the step of growing a capacitor dielectric layer on the first conductive layer comprises growing at least one of a copper oxide layer and a tantalum oxide layer.
